(19) United States
(12) Patent Application Publication
(10) Pub. No.: US 2025/0185381 A1
(43) Pub. Date: Jun. 5, 2025

(54) INTERCONNECTING THERMOPHOTOVOLTAIC DEVICES IN SHINGLE ARRANGEMENT

(71) Applicant: Antora Energy, Inc., Sunnyvale, CA (US)

(72) Inventors: Jan Moritz Limpinsel, San Mateo, CA (US); Jason Tolentino, San Jose, CA (US); Brett Michael Barnes, Toronto (CA)

(21) Appl. No.: 19/044,219

(22) Filed: Feb. 3, 2025

Related U.S. Application Data
(63) Continuation of application No. PCT/US2023/071615, filed on Aug. 3, 2023.
(60) Provisional application No. 63/394,841, filed on Aug. 3, 2022.

(51) Int. Cl. H10F 19/90; H10F 71/00; H10F 77/63

(52) U.S. Cl. CPC H10F 19/902; H10F 71/137; H10F 77/63

(57) ABSTRACT

Photovoltaic devices can include photovoltaic cells can include a wafer foil having a first side and a second side, a front metal contact coupled to the first side, a back metal layer coupled to the second side, and a patterned layer coupled to the back metal layer. The patterned layer can include an electrically insulating region and an electrical conductor that contacts the back metal layer. The electrically insulating region can include a die attach film. Multiple photovoltaic cells can be combined in a shingle arrangement to form an interconnected device wherein the front metal contact of one cell contacts the electrical contact of another cell. A die attach film can be used as the electrically insulating region to create the interconnected device without adding additional insulation between the cells. Devices can include materials suitable for thermophotovoltaic applications.

### RELATED APPLICATIONS

This application is a continuation of International Patent Application No. PCT/US2023/071615, filed Aug. 3, 2023, which claims the benefit of U.S. Provisional Application No. 63/394,841, filed Aug. 3, 2022, each of which is incorporated herein by reference in its entirety.

### TECHNICAL FIELD

The present disclosure relates to the field of solar devices, such as thermophotovoltaic devices. Some embodiments set forth below describe interconnecting thermophotovoltaic devices in a shingle arrangement.

### BACKGROUND OF INVENTION

There is an increased demand for renewable energy solutions, such as wind, heat, and solar energy, which has led to a need for scalable solutions. Improvements in thermophotovoltaic (TPV) systems, which convert heat (e.g., industrial waste heat) energy into electricity, are turning them into efficient and economically viable power systems. Conventionally, TPV systems comprise cells laid down next to each other with wire bonds applied in between to interconnect the cells, which is typically a slow and serial process.

The industry has turned to laying down TPV cells in a shingle arrangement for greater density and elimination of wire bonds. However, shingling TPV cells requires insulation between the overlapping portions of the TPV cells, which typically involves putting one row of cells down, placing an insulator, and then placing a next row of cells on top of the insulated portion.

Thus, assembling such TPV cells in a shingle arrangement remains an inefficient and serial process, and an improved process for interconnecting TPV devices in a shingle arrangement is desired.

### SUMMARY

Some aspects of this disclosure are directed to a photovoltaic device comprising a photovoltaic cell. Some photovoltaic cells include a wafer foil having a first side and a second side, a front metal contact coupled to the first side of the wafer foil, a back metal layer coupled to the second side of the wafer foil, and a patterned layer coupled to the back metal layer opposite the wafer foil. The patterned layer comprising an electrically insulating region and an electrical conductor that contacts the back metal layer.

In some examples, the electrically insulating region comprises a die attach film. Multiple photovoltaic cells can be combined in a shingle arrangement to form an interconnected device wherein the front metal contact of one cell contacts the electrical contact of another cell. A die attach film can be used as the electrically insulating region to create the interconnected device without adding additional insulation between the cells. A die attach film can also be used as the electrically conductive region, and the combination of conductive and non-conductive regions in a die attach film can be called a patterned die attach film.

In some embodiments, patterned die attach films can be used to provide adhesion between a cell and an underlying component, such as another cell or a substrate. Additionally or alternatively, patterned die attach films can include thermally conductive material to provide thermal conductivity between a cell and an underlying component. A patterned die attach film can provide selective electrical communication between portions of the cell and portions of an underlying component while providing electrical insulation between portions of the cell and other portions of an underlying component and/or another underlying component.

In some examples, the electrically insulating region comprises a thermally conductive, electrically insulating material. In some cases, thermally conductive materials can help dissipate heat in thermophotovoltaic applications.

Some aspects of this disclosure are directed to wafer systems for processing to create a plurality of photovoltaic cells. A wafer system can include a wafer foil having a first side and a second side, a plurality of front metal contacts coupled to the first side of the wafer foil and arranged in front metal pattern, and a back metal layer coupled to the second side of the wafer foil. The wafer system can include a front side corresponding to the first side of the wafer foil and a back side corresponding to the second side of the wafer foil.

The patterned layer can include a non-conductive insulator, such as a thermally conductive, electrically insulating material and a plurality of electrical conductors arranged in a back pattern. In some cases, the non-conductive insulator comprises a die attach film. In some cases, the electrically-conductive regions also comprise a die attach film, and the combination of conductive and non-conductive regions in a die attach film can be called a patterned die attach film.

Some aspects of this disclosure are directed to methods, such as methods for making cells for interconnecting structures. Some methods include adding a patterned layer to a wafer system. A wafter system can include a wafer foil having a first side and a second side opposite the first side, a plurality of front metal contacts coupled to the first side of the wafer foil and arranged in front metal pattern, and a back metal layer coupled to the second side of the wafer foil. The patterned layer can include a non-conductive insulator and a plurality of electrical conductors arranged in a back pattern.

Methods can include attaching a dicing tape to a combined patterned layer and wafer system and dicing the combined wafer system and patterned layer at intervals into a plurality of cells. In some cases, the wafer is diced such that each of the plurality of cells includes only one of the front metal contacts of the wafer system on a first side of the cell and only one of the plurality of electrical conductors of the patterned layer on a second side of the cell.

Methods can include releasing at least a first cell of the plurality of cells and a second cell from the plurality of cells from the dicing tape. Methods can further include electrically coupling the front metal contact of the first cell to the electrical conductor of the second cell such that the first cell and the second cell are electrically coupled in series in a shingle arrangement. In some examples, the first cell and second cell form at least a part of an interconnected device.

### BRIEF DESCRIPTION OF THE DRAWINGS

Various non-limiting and non-exhaustive aspects and features of the present disclosure are described hereinbelow with references to the drawings, wherein:

FIG. 1A is a back side of a simplified representation of an exemplary wafer prepared with a patterned film comprising non-conductive and conductive areas.

FIG. 1B is a cross-section view of an exemplary cell from the exemplary wafer in FIG. 1A.

FIG. 2A is a back side view of a simplified representation of an exemplary wafer prepared with a non-conductive insulator.

FIG. 2B is a cross-section view of an exemplary cell from the exemplary wafer in FIG. 2B.

FIG. 3A is a back side view of a simplified representation of an exemplary wafer printed on its back side with a non-conductive and conductive pattern.

FIG. 3B is a cross-section view of an exemplary cell from the exemplary wafer in FIG. 3B.

FIG. 4A is a back side view of a simplified representation of an exemplary wafer printed on its back side with a non-conductive and conductive pattern.

FIG. 4B is a cross-section view of an exemplary cell from the exemplary wafer in FIG. 4B.

FIG. 5A is a back side view of a simplified representation of an exemplary wafer printed on its back side with a non-conductive and conductive pattern.

FIG. 5B is a cross-section view of an exemplary cell from the exemplary wafer in FIG. 5B.

FIGS. 6A and 6B are flow diagrams illustrating methods for interconnecting TPV devices in a shingle arrangement using a wafer prepared with a patterned film comprising non-conductive and conductive areas.

FIG. 7 is a flow diagram illustrating a method for interconnecting TPV devices in a shingle arrangement using a wafer prepared with a non-conductive insulator.

FIG. 8 is a flow diagram illustrating a method for interconnecting TPV devices in a shingle arrangement using a wafer printed on its back side with a non-conductive and conductive pattern.

FIG. 9 is a flow diagram illustrating a method for interconnecting TPV devices in a shingle arrangement using a wafer printed on its back side with a non-conductive and conductive pattern.

FIG. 10A shows an example cell.

FIG. 10B shows examples cells in a shingle arrangement.

Like reference numbers and designations in the various drawings indicate like elements. Skilled artisans will appreciate that elements in the Figures are illustrated for simplicity and clarity, and have not necessarily been drawn to scale, for example, with the dimensions of some of the elements in the figures exaggerated relative to other elements to help to improve understanding of various embodiments. Common, well-understood elements that are useful or necessary in a commercially feasible embodiment are often not depicted in order to facilitate a less obstructed view of these various embodiments.

### DETAILED DESCRIPTION

The invention is directed to interconnecting thermophotovoltaic (TPV) devices in a shingle arrangement. The Figures and the following description describe certain embodiments by way of illustration only. One of ordinary skill in the art will readily recognize from the following description that alternative embodiments of the structures and methods illustrated herein may be employed without departing from the principles described herein. Reference will now be made in detail to several embodiments, examples of which are illustrated in the accompanying figures.

The systems and methods described herein disclose interconnecting TPV devices in a shingle arrangement wherein insulation is applied at a wafer level to enable efficient arrangement of wafers comprising a plurality of TPV devices. Several methods are provided herein for pre-patterning a side of a wafer of TPV cells such that each cell is insulated prior to arranging the TPV cells in a system so that rows of TPV cells may be laid in a shingle arrangement without serially adding insulation in between layers. In some embodiments, an underside of a wafer may be prepared with a pre-patterned die attach film (e.g., DAF), in some examples in combination with dicing tape (e.g., D-DAF). In some embodiments, a non-patterned non-conductive die attach film (e.g., combined with dicing tape) may be applied to a wafer that may be patterned after bonding. In some embodiments, conductive and non-conductive epoxies may be applied to a side of a wafer that is then bonded on an opposite side of the wafer. In some examples, these adhesive films, which in some cases might be patterned, may be prepared by printing, or otherwise dispensing, different epoxies (e.g., conductive or non-conductive) onto a suitable film and then partially curing (“B-staging”) them.

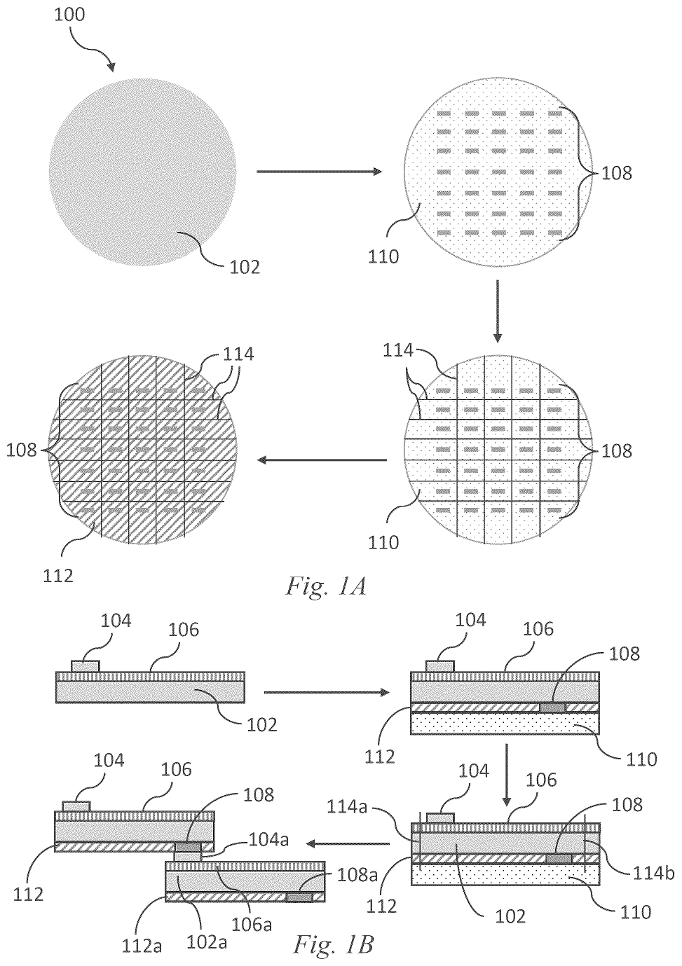

FIG. 1A is a back side of a simplified representation of an exemplary wafer prepared with a patterned film comprising non-conductive and conductive areas. FIG. 1B is a cross-section view of an exemplary cell from the exemplary wafer in FIG. 1A. In some examples, wafer system 100 may comprise a plurality of thermophotovoltaic (TPV) devices. Wafer system 100 may comprise wafer foil 106 metalized on back with metal layer 102 and comprising a front metal 104 patterned onto wafer foil 106.

In some examples, a patterned adhesive film (e.g., a patterned die attach film), comprises a non-conductive insulator 112 and pre-patterned plurality of conductors 108 (e.g., electrically conductive adhesives (ECAs)), optionally in combination with a dicing tape 110 (e.g., pre-laminated DDAF). For example, a pre-patterned DAF may be pre-cut to accommodate a plurality of conductors 108 in a pattern such that when wafer system 100 is diced, a cell from wafer system 100 may be placed in a shingle arrangement with another cell (e.g., diced from wafer system 100 or another wafer) such that the front metal feature of the other cell (e.g., front metal 104) aligns with a conductor (e.g., one of the plurality of conductors 108) of the other cell.

In some examples, a wafer, prior to dicing, has a plurality of front metal contacts (e.g., 104) positioned thereon and arranged in a front metal pattern. In some such embodiments, the wafer further includes, prior to dicing, a plurality of conductors (e.g., 108) positioned on an opposite side of the wafer and arranged in a back pattern. In some examples, the front metal pattern and the back pattern are approximately the same pattern. For instance, in some examples, a front metal pattern includes a first spatial period in a first direction (e.g., a first distance between centers of adjacent front metal contacts along the first direction) and a second spatial period in a second direction (e.g., a second distance between centers of adjacent metal contacts along the second direction, different from the first). In some such examples, the back pattern includes the first spatial period in the first direction and the second spatial period in the second direction (e.g., wherein a distance between centers of adjacent conductors is the first distance along the first direction and a distance between centers of adjacent conductors is the second distance along the second direction).

In some such embodiments, the wafer can be diced into cells having a lateral dimension approximately equal to the first distance along the first direction and the second distance along the second direction. Thus, in some such examples, each resulting cell includes a first side having a front metal contact positioned in approximately the same position from cell to cell, and a second side, opposite the first, having a conductor positioned at approximately the same position from cell to cell. In some such examples, patterning and dicing the wafer in such a way can result in a plurality of approximately the same cells. Such cells can be consistently stacked in a shingle arrangement, as a relationship between the front metal contact of a first cell and a conductor of a second cell is predictable and repeatable.

In some embodiments, the front metal pattern and the back pattern are approximately the same pattern, and in some such examples, the front metal contacts (e.g., 104) are approximately the same size as the conductors (e.g., 108). In other examples, the front metal pattern and the back pattern are approximately the same pattern, and in some such examples, the front metal contacts (e.g., 104) are different sizes as the conductors (e.g., 108). However, even in such examples, a common pattern (e.g., common spatial period in a first direction and a second direction) shared by the front metal pattern and the back pattern can yield predictable shingle arrangements of individual cells after dicing as described elsewhere herein.

In some examples, a wafer is diced such that each of a plurality of resulting cells includes only one of a plurality of front metal contacts and only one of the plurality of electrical conductors. In other examples, the front metal pattern and/or back pattern can be such that dicing results in a cell that includes a plurality of front metal contacts and/or a plurality of conductors. For instance, in some examples, the back pattern can be such that a plurality of conductors (e.g., 108) are included in a single cell to provide multiple points of electrical connection between, for example, a back metal layer 102 of the cell and one or more underlying components, such as a substrate to which the cell is later bonded.

In some examples, both the non-conductive insulator 112 and the plurality of conductors 108 may have high thermal conductivity, although their electrical conductivities may be very different. In some embodiments, conductor 108 may comprise a conductive epoxy, a solder paste, or other electrically conductive material. In some examples, insulator 112 comprises a non-conductive epoxy. Example insulators that include high thermal conductivity include, for example, AlN, Al2O3, SiN, and diamond. In some examples, a DAF includes one or more such materials as particles embedded into a polymer matrix.

Once the patterned film comprising non-conductive insulator 112 and plurality of conductors 108 is in place, wafer system 100 may be diced (e.g., cut through some or all layers). Dicing can occur, for example, along lines 114 in FIG. 1A. In some examples, dicing comprises dicing through a wafer system 100 such that the cut line extends through the wafer foil 106, metal layer 102, and insulator 112. In some such embodiments, the cut does not extend all the way through the dicing tape 110, for example, as shown by cuts 114a, 114b extending through wafer foil 106, metal layer 102, and insulator 112, but not through dicing tape 110.

The dicing tape 110 may be released (e.g., adhesive bond of dicing tape 110 broken or otherwise disturbed by exposure to ultraviolet (UV) light, heat, or other release mechanism (e.g., mechanical) to separate dicing tape 110 from non-conductive insulator 112). One or more cells from wafer system 100 may then be picked and assembled into a shingle arrangement, for example, wherein conductor 108 of a cell lines up with front metal 104a of a second cell, which includes its own metal layer 102a, wafer foil 106a, front metal 104b, insulator 112a and conductor 108a, as shown in FIG. 1B. Global alignment markers may be used to align features on wafer system 100 (e.g., front metal 104 to pre-patterned plurality of conductors (e.g., plurality of conductors 108) on a patterned DAF).

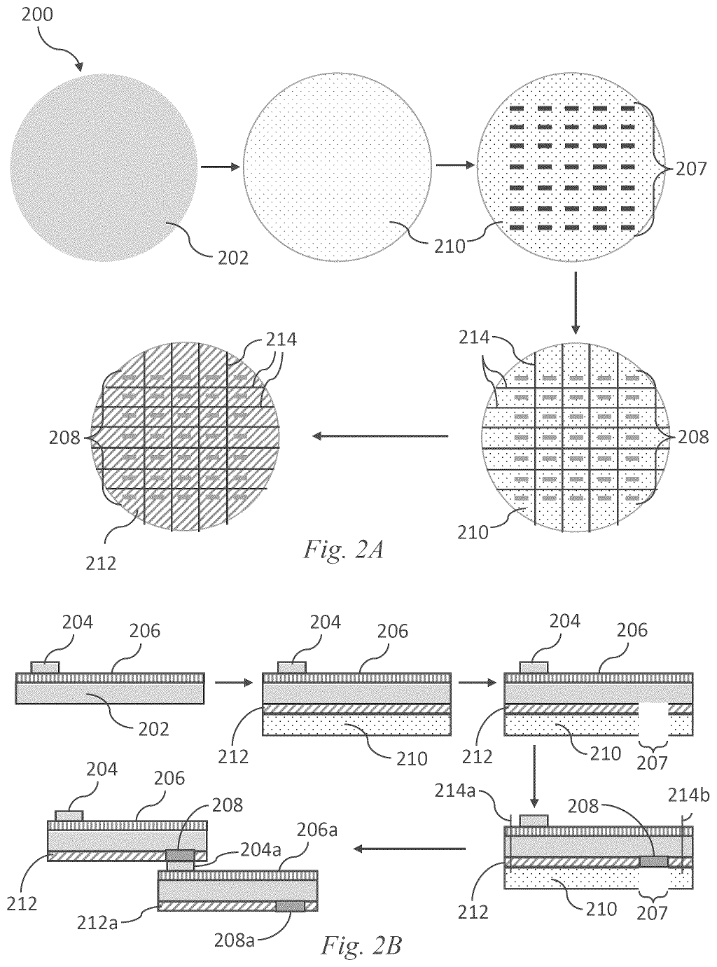

FIG. 2A is a back side view of a simplified representation of an exemplary wafer prepared with a non-conductive insulator. FIG. 2B is a cross-section view of an exemplary cell from the exemplary wafer in FIG. 2B. Wafer system 200 may comprise wafer foil 206 metalized on back with metal layer 202 and comprising a front metal 204 patterned onto wafer foil 206. In some examples, a non-conductive insulator 212, optionally in combination with a dicing tape 210, may be layered onto metal layer 202. A back pattern 207 may be cut into the non-conductive insulator 212 and dicing tape 210 layers. In some examples, the back pattern 207 may comprise busbar-sized openings—busbars may be of various sizes and shapes, and such openings may be sized and shaped according to a desired busbar. In some examples, the back pattern 207 may be cut using a laser or other appropriate cutting implement. The holes of the back pattern 207 may be filled with conductive material 208 (e.g., ECAs), in some examples, using a printing device. The wafer can be diced into cells along lines 214, and in some examples, the dicing can include cutting through wafer foil 206, metal layer 202, and insulating layer 212, but not through dicing tape 210 (e.g., as shown via cut lines 214a, 214b).

The dicing tape 210 may be released and the wafer system 200 may be picked and assembled into a shingle arrangement (e.g., aligning conductor 208 with front metal 204a on another wafer comprising wafer foil 206a, non-conductive insulator 212a, and conductor 208a, which in turn may be aligned with the front metal portion of yet another wafer system), as shown in FIG. 2B, as described herein. In some examples, releasing dicing tape 210 may occur within a few hours of filling the back pattern 207 with conductive material 208, even if conductive material 208 has not yet set (e.g., dried).

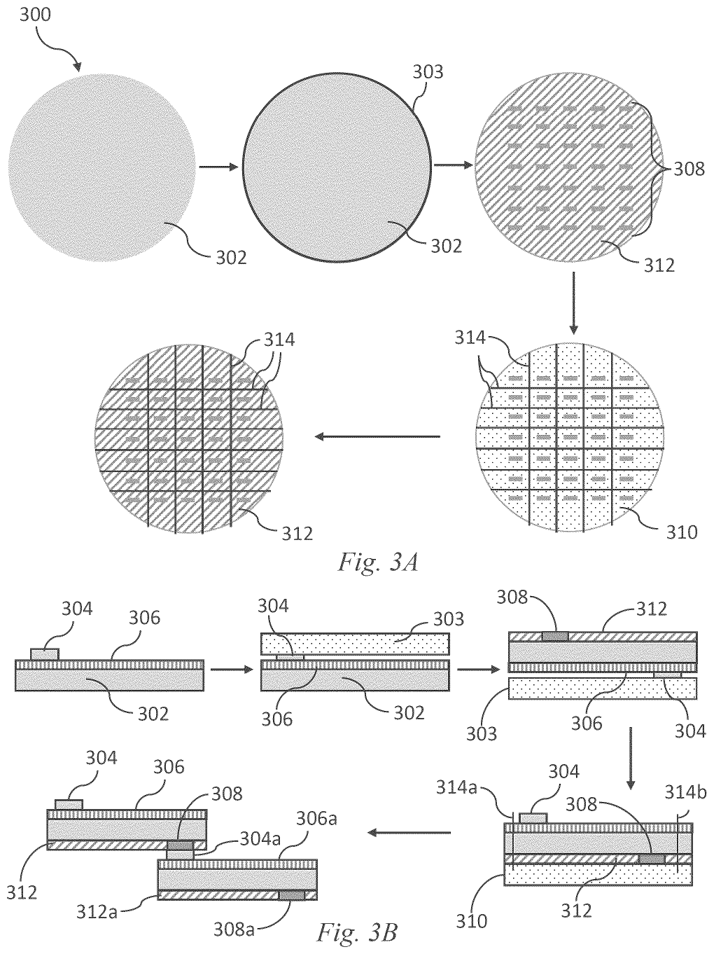

FIG. 3A is a back side view of a simplified representation of an exemplary wafer printed on its back side with a non-conductive and conductive pattern. FIG. 3B is a cross-section view of an exemplary cell from the exemplary wafer in FIG. 3B. In some examples, wafer system 300 may comprise a plurality of TPV devices. In wafer system 300, wafer foil 306 may be metalized on back with metal layer 302 and may have a front metal 304 patterned onto its front side. In some examples, a release tape 303 may be mounted onto a front side (e.g., “sunny” side) of wafer system 300, thereby enabling wafer system 300 to be turned (i.e., flipped) over such that the back side may be exposed for application of further layers onto the back side. In other examples, wafer system 300 may be secured and/or stabilized with its front side down using other mechanisms (e.g., vacuum chuck, magnet, electrostatic chuck, and the like) for application of said further layers. A back pattern of conductive material 308, along with the non-conductive insulator 312, may be applied onto said back side of wafer system 300, to form a patterned DAF. In some examples, application of conductive material 308 and non-conductive insulator 312 may comprise printing (e.g., inkjet printing, screen printing, and the like) of conductive and non-conductive materials onto said back side. In some examples, conductive material 308 may comprise a conductive epoxy. In some examples, conductive material 308 comprises a solder paste. In some examples, non-conductive insulator 312 may comprise a non-conductive epoxy. In some examples, dicing tape 310 may be bonded onto the back side (e.g., onto non-conductive insulator 312 and/or conductive material 308) and the release tape released (e.g., using UV light or other release mechanisms, as described herein) from the front side of wafer system 300. Wafer system 300 may then be diced, dicing tape 310 may be released, and the wafer system 300 may be picked and assembled into a shingle arrangement, as shown in FIG. 3B, as described herein. For example, conductor 308 can be aligned with front metal 304a on another wafer comprising wafer foil 306a, non-conductive insulator 312a, and conductor 308a, which in turn may be aligned with the front metal portion of yet another wafer system.

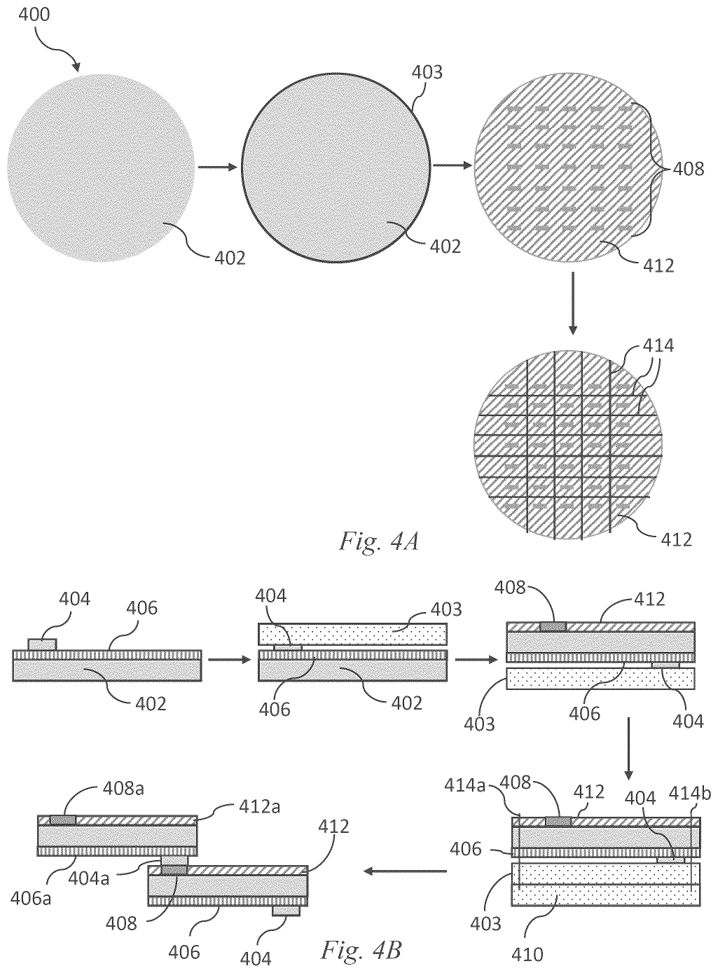

FIG. 4A is a back side view of a simplified representation of an exemplary wafer printed on its back side with a non-conductive and conductive pattern. FIG. 4B is a cross-section view of an exemplary cell from the exemplary wafer in FIG. 4B. In some examples, wafer system 400 may comprise a plurality of TPV devices. In wafer system 400, wafer foil 406 may be metalized on back with metal layer 402 and may have a front metal 404 patterned onto its front side. In some examples, a release tape 403 may be mounted onto a front side (e.g., “sunny” side) of wafer system 400, thereby enabling wafer system 400 to be turned (i.e., flipped) over such that the back side may be exposed for application of further layers onto the back side. In other examples, wafer system 400 may be secured and/or stabilized with its front side down using other mechanisms (e.g., vacuum chuck, magnet, electrostatic chuck, and the like) for application of said further layers. A back pattern of conductive material 408, along with the non-conductive insulator 412, may be applied onto said back side of wafer system 400, to form a patterned DAF. In some examples, application of conductive material 408 and non-conductive insulator 412 may comprise printing (e.g., inkjet printing, screen printing, and the like) of conductive and non-conductive materials onto said back side. In some examples, conductive material 408 may comprise a conductive epoxy. In some examples, conductive material 408 comprises a solder paste. In some examples, non-conductive insulator 412 may comprise a non-conductive epoxy.

In some examples, dicing tape 410 may be bonded onto the front side (e.g., onto release tape 403) such that the wafer may be diced with the back side of the wafer system facing upward (e.g., with the “sunny side” down), for example, along lines 414 (e.g., lines 414a and 414b in FIG. 4B). In some examples, release tape 403 comprises a dicing tape. For instance, in some examples, release tape 403 comprises a dicing tape that includes a release liner such that release tape 403 can be mounted to the wafer system 400 prior to applying a back pattern of conductive material 408 and non-conductive insulator 412 to form a patterned DAF. The release tape can be used to support the structure for subsequent dicing.

After dicing, dicing tape 410 and release tape 403 may be released, and the wafer system 400 may be picked and assembled into a shingle arrangement, as shown in FIG. 4B, similar to as described herein. For example, conductor 408 can be aligned with front metal 404a on another wafer comprising wafer foil 406a, non-conductive insulator 412a, and conductor 408a, which in turn may be aligned with the front metal portion of yet another wafer system. In some examples, the shingle arrangement can be assembled sunny side down, such as shown in FIG. 4B. In some examples, an interconnected assembly resulting from the shingle arrangement of two or more cells is formed sunny side down. The interconnected assembly can be flipped and cured in a sunny side up configuration.

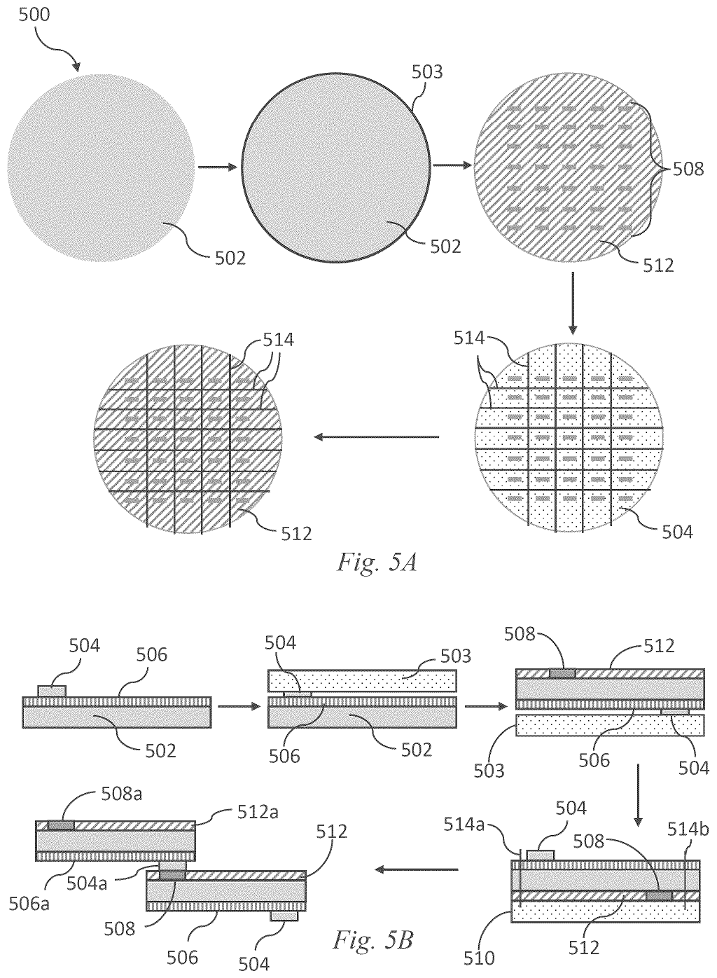

FIG. 5A is a back side view of a simplified representation of an exemplary wafer printed on its back side with a non-conductive and conductive pattern. FIG. 5B is a cross-section view of an exemplary cell from the exemplary wafer in FIG. 5B. In some examples, wafer system 500 may comprise a plurality of TPV devices. In wafer system 500, wafer foil 506 may be metalized on back with metal layer 502 and may have a front metal 504 patterned onto its front side. In some examples, a release tape 503 may be mounted onto a front side (e.g., “sunny” side) of wafer system 500, thereby enabling wafer system 500 to be turned (i.e., flipped) over such that the back side may be exposed for application of further layers onto the back side. In other examples, wafer system 500 may be secured and/or stabilized with its front side down using other mechanisms (e.g., vacuum chuck, magnet, electrostatic chuck, and the like) for application of said further layers. A back pattern of conductive material 508, along with the non-conductive insulator 512, may be applied onto said back side of wafer system 500, to form a patterned DAF. In some examples, application of conductive material 508 and non-conductive insulator 512 may comprise printing (e.g., inkjet printing, screen printing, and the like) of conductive and non-conductive materials onto said back side. In some examples, conductive material 508 may comprise a conductive epoxy. In some examples, conductive material 508 comprises a solder paste. In some examples, non-conductive insulator 512 may comprise a non-conductive epoxy.

Similar to as discussed with respect to FIGS. 3A and 3B, in some examples, dicing tape 510 may be bonded onto the back side (e.g., onto non-conductive insulator 512 and/or conductive material 508) and the release tape released (e.g., using UV light or other release mechanisms, as described herein) from the front side of wafer system 500. Wafer system 500 may then be diced (e.g., along lines 514, shown as 514a and 514b in FIG. 5B), dicing tape 510 may be released, and the wafer system 500 may be picked and assembled into a shingle arrangement, as shown in FIG. 5B. As shown in FIG. 5B, a shingle arrangement can be constructed sunny side down. For example, conductor 508 can be aligned with front metal 504a on another wafer comprising wafer foil 506a, non-conductive insulator 512a, and conductor 508a, which in turn may be aligned with the front metal portion of yet another wafer system, and wherein the front metal 504a of a cell is set down onto conductor 508 of a different cell with the front sides of the cells facing downward. Like discussed with respect to FIG. 4B, in some examples, an interconnected assembly resulting from the shingle arrangement of two or more cells can be formed sunny side down, and the interconnected assembly can be flipped and cured in a sunny side up configuration.

In some example processes, a DAF can be attached to a back side of a wafer (e.g., to a back metal layer) positioned sunny side down. In some examples, such a wafer is diced sunny side down and cells can be picked from the diced wafer and placed in an interconnected assembly sunny side down; the interconnected assembly can be inverted and cured in a sunny side up configuration. In other processes, the wafer is flipped, diced sunny side up, and flipped again so that it is sunny side down. In some such examples, cells can be picked from the diced wafer and placed in an interconnected assembly sunny side down; the interconnected assembly can be inverted and cured in a sunny side up configuration.

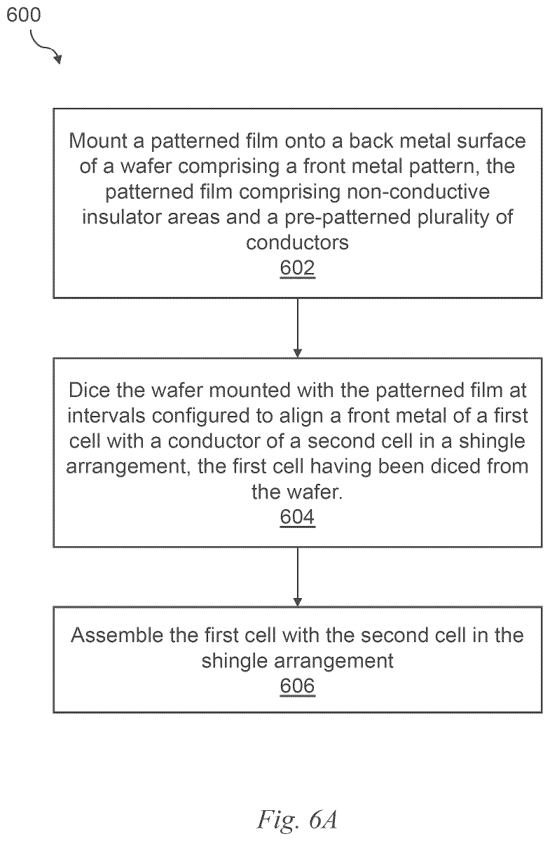

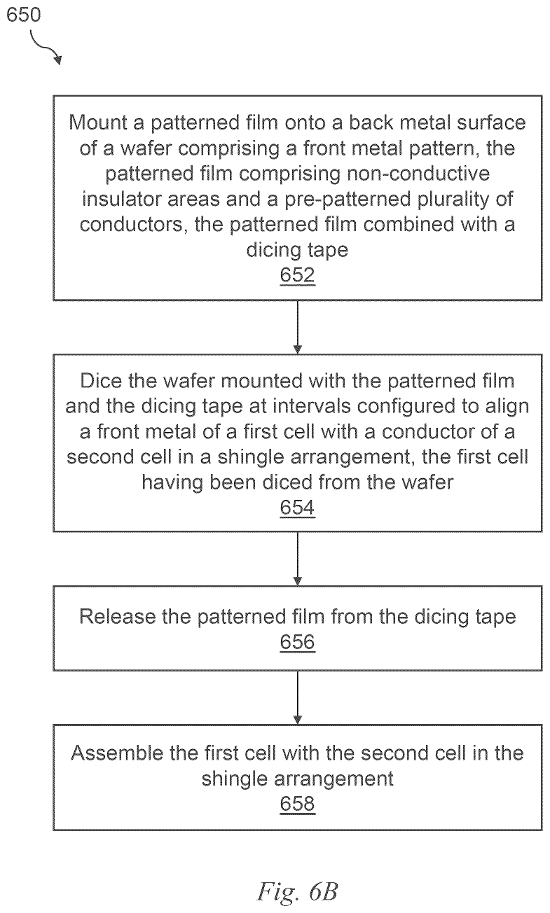

FIGS. 6A and 6B are flow diagrams illustrating methods for interconnecting TPV devices in a shingle arrangement with a wafer prepared with a patterned film comprising non-conductive and conductive areas. Method 600 may begin with mounting a patterned film onto a back metal surface of a wafer comprising a front metal pattern at step 602. In some examples, the patterned film may comprise non-conductive insulator areas and a pre-patterned plurality of conductors, to form a patterned DAF. The wafer mounted with the patterned film may be diced, at step 604, at intervals configured to align a front metal of a first cell with a conductor of a second cell in a shingle arrangement. In some examples, the first cell may have been diced from the wafer. In some examples, the second cell may have been diced from either the wafer or another wafer. The first cell may be assembled with the second cell in the shingle arrangement at step 606. In other examples, one or more additional cells from the wafer or another wafer may be assembled in the shingle arrangement with the first cell and/or the second cell.

Method 650 may begin with mounting a patterned DAF onto a back metal surface of a wafer comprising a front metal pattern. In some examples, the patterned DAF may comprise non-conductive insulator areas and a pre-patterned plurality of conductors. In some examples, the patterned film may be combined with a dicing tape, such as shown at step 652. The wafer mounted with the patterned film and the dicing tape may be diced, at step 654, at intervals configured to align a front metal of a first cell with a conductor of a second cell in a shingle arrangement. In some examples, the first cell may have been diced from the wafer. In some examples, the second cell may have been diced from either the wafer or another wafer. The patterned film may be released from the dicing tape at step 656, for example, using UV light, heat, or other mechanisms, as described herein. The first cell may then be assembled with the second cell in the shingle arrangement at step 658, for example, wherein a conductor of the first cell aligns with a front metal of the second cell, or vice versa, as described herein. In other examples, one or more additional cells from the wafer or another wafer may be assembled in the shingle arrangement with the first cell and/or the second cell.

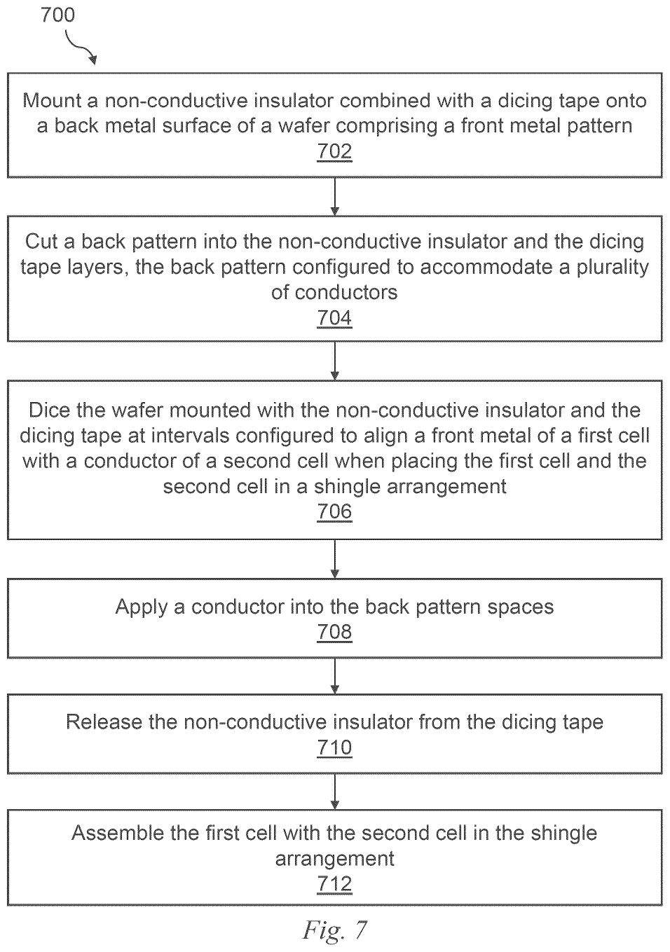

FIG. 7 is a flow diagram illustrating a method for interconnecting TPV devices in a shingle arrangement with a wafer prepared with a patterned DAF. Method 700 may begin with mounting a non-conductive insulator combined with a dicing tape onto a back metal surface of a wafer comprising a front metal pattern at step 702. A back pattern may be cut into the non-conductive insulator and the dicing tape layers at step 704. In some examples, the back pattern may be configured to accommodate a plurality of conductors. The wafer mounted with the non-conductive insulator and the dicing tape may be diced, at step 706, at intervals configured to align a front metal of a first cell with a conductor of a second cell when placing the first cell and the second cell in a shingle arrangement. In some examples, the first cell may be diced from the wafer. In some examples, the second cell may be diced from the wafer or another wafer. A conductor (e.g., conductive material) may be applied (e.g., deposited, printed, and the like) into the back pattern spaces at step 708. The non-conductive insulator may be released from the dicing tape at step 710. The first cell may be assembled with the second cell in the shingle arrangement at step 712, in alignment as described herein. In other examples, one or more additional cells from the wafer or another wafer may be assembled in the shingle arrangement with the first cell and/or the second cell.

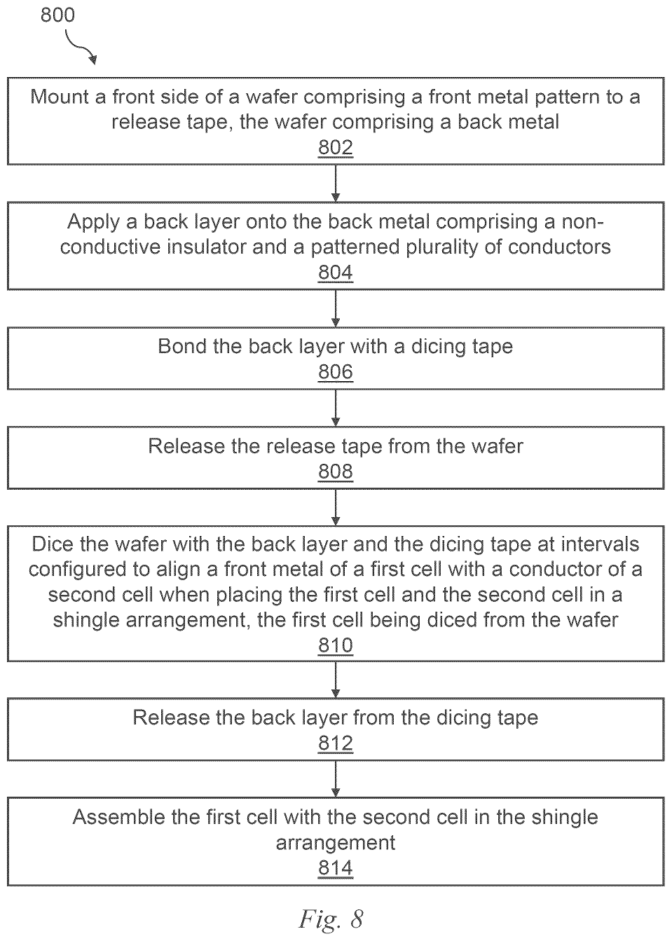

FIG. 8 is a flow diagram illustrating a method for interconnecting TPV devices in a shingle arrangement with a wafer printed on its back side with a non-conductive and conductive pattern forming a patterned DAF. Method 800 may begin with mounting a front side of a wafer comprising a front metal pattern to a release tape, at step 802. In some examples, the wafer may comprise a back metal. In some examples, the release tape may comprise UV release tape, which may be released with UV light or heat. A back layer may be applied onto the back metal at step 804, the back layer comprising a non-conductive insulator and a patterned plurality of conductors. In some examples, the non-conductive insulator may fill the space around the patterned plurality of conductors (e.g., surrounding said patterned plurality of conductors). In some examples, the non-conductive insulator and conductors may comprise non-conductive and conductive epoxies, respectively. In some examples, this back layer may be printed on using various methods, as described herein. The back layer may be bonded with a dicing tape at step 806. The release tape may then be released from the wafer at step 808 (e.g., using UV light, heat, or other release mechanisms as described herein). The wafer with the back layer and the dicing tape may be diced at step 810, for example, at intervals configured to align a front metal of a first cell with a conductor of a second cell when placing the first cell and the second cell in a shingle arrangement. In some examples, the first cell has been diced from the wafer. In some examples, the second cell has been diced from either the wafer or another wafer. The wafer may be released from the dicing tape at step 812. The first cell may be assembled with the second cell in the shingle arrangement at step 814. In other examples, one or more additional cells from the wafer or another wafer may be assembled in the shingle arrangement with the first cell and/or the second cell. As described herein, in various examples, assembling the cells in a shingle arrangement can be performed sunny side up or sunny side down.

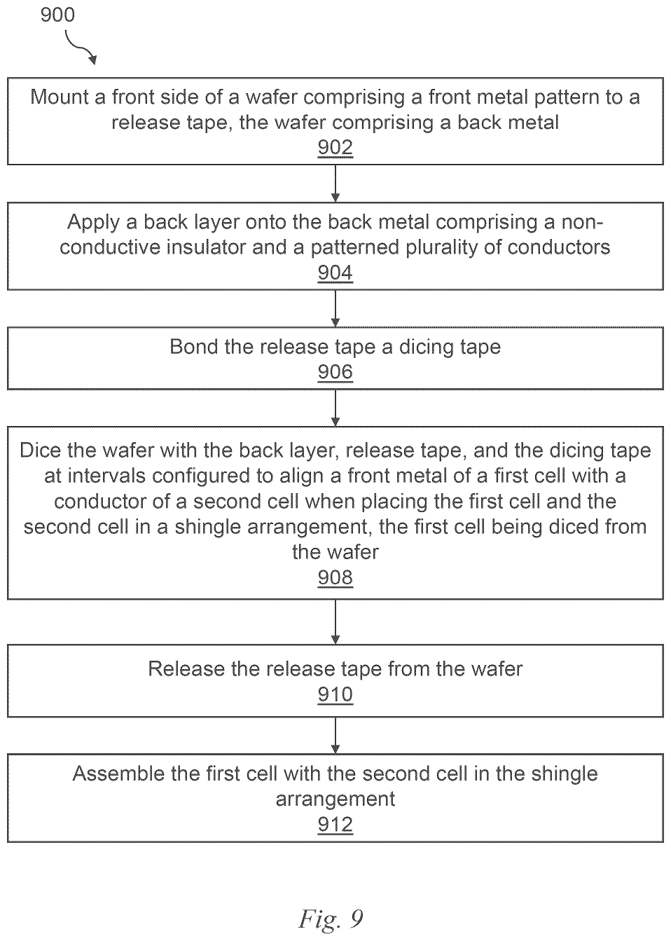

FIG. 9 is a flow diagram illustrating a method for interconnecting TPV devices in a shingle arrangement with a wafer printed on its back side with a non-conductive and conductive pattern. Method 900 may begin with mounting a front side of a wafer comprising a front metal pattern to a release tape, at step 902. In some examples, the wafer may comprise a back metal. In some examples, the release tape may comprise UV release tape, which may be released with UV light or heat. A back layer may be applied onto the back metal at step 904, the back layer comprising a non-conductive insulator and a patterned plurality of conductors. In some examples, the non-conductive insulator may fill the space around the patterned plurality of conductors (e.g., surrounding said patterned plurality of conductors). In some examples, the non-conductive insulator and conductors may comprise non-conductive and conductive epoxies, respectively. In some examples, this back layer may be printed on using various methods, as described herein.

The release tape may be bonded with a dicing tape at step 906. As described elsewhere herein, in some examples, the release tape of step 902 serves as a dicing tape, for example, comprising a dicing tape having a release liner. In some such examples, separate step 906 is omitted, as the wafer may be diced without an additional dicing tape addition step. The wafer with the back layer and the dicing tape (e.g., separate from release tape or wherein the release tape comprises a dicing tape) may be diced at step 908, for example, at intervals configured to align a front metal of a first cell with a conductor of a second cell when placing the first cell and the second cell in a shingle arrangement. In some examples, the first cell has been diced from the wafer. In some examples, the second cell has been diced from either the wafer or another wafer. The release tape may then be released from the wafer at step 910 (e.g., using UV light, heat, or other release mechanisms as described herein). In some examples, the release tape is released from the dicing tape prior to releasing the release tape from the wafer. In other examples, dicing tape is not separately released, and releasing the release tape can result in both the release tape and dicing tape being removed from the wafer. In still other examples, the release tape also serves as a dicing tape, and releasing the release tape at step 910 comprises removing tape that serves as both the release tape and the dicing tape. The first cell may be assembled with the second cell in the shingle arrangement at step 912. In other examples, one or more additional cells from the wafer or another wafer may be assembled in the shingle arrangement with the first cell and/or the second cell. As described herein, in various examples, assembling the cells in a shingle arrangement can be performed sunny side up or sunny side down.

In some examples, more cells (e.g., diced from wafer systems 100, 200, 300, 400, and/or 500 in FIGS. 1A, 2A, 3A, 4A, and 5A, respectively) may be added to the shingle arrangements described herein and shown in FIGS. 1B, 2B, 3B, 4B, and 5B. In some examples, wafers described herein may comprise tens to one hundred or more cells (e.g., TPV devices). In some examples, wafers and wafer foils may comprise epitaxial wafer foils (e.g., comprising a film grown by epitaxy). In other examples, crystalline growth techniques (i.e., not epitaxial), including monocrystalline and polycrystalline, amorphous growth techniques (e.g., chemical bath deposition), and other growth techniques may be used.

In some example processes, a patterned DAF can be attached to a back side of a wafer (e.g., to a back metal layer) positioned sunny side down. In some examples, such a wafer is diced sunny side down and cells can be picked from the diced wafer and placed in an interconnected assembly sunny side down; the interconnected assembly can be inverted and cured in a sunny side up configuration. In other processes, the wafer is flipped, diced sunny side up, and flipped again so that it is sunny side down. In some such examples, cells can be picked from the diced wafer and placed in an interconnected assembly sunny side down; the interconnected assembly can be inverted and cured in a sunny side up configuration.

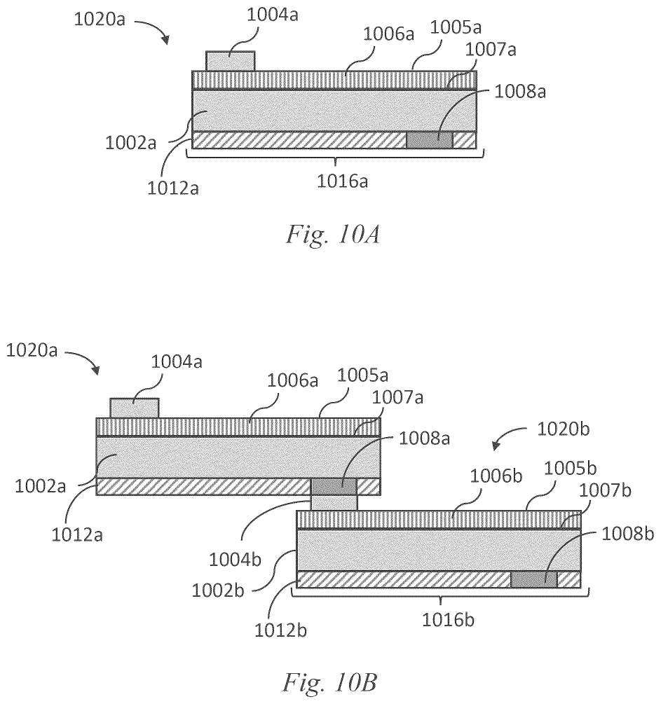

FIG. 10A shows an example cell. The cell 1020a can include a wafer foil 1006a having a first side 1005a and a second side 1007a opposite the first side 1005a. In some examples, the wafer foil 1006a can include a semiconductor device, such as a photovoltaic device, and in some examples, a thermophotovoltaic device. The cell 1020a can include a front metal contact 1004a coupled to the first side 1005a of the wafer foil 1006a and a back metal layer 1002a coupled to the second side 1007a of the wafer foil 1006a. In some examples, the front metal contact 1004a and the back metal layer 1002a act as contacts for the semiconductor device of the wafer foil 1006a (e.g., contacts for a thermophotovoltaic device). The cell 1020a can further include a patterned layer 1016a coupled to the back metal layer 1002a opposite the wafer foil 1006a. The patterned layer 1016a can include an electrically insulating region 1012a and an electrical conductor 1008a that contacts the back metal layer 1002a. In some such examples, the electrical conductor 1008a of the patterned layer 1016a can similarly serve as a contact for the device of the wafer foil 1006a, for example, via the back metal layer 1002a. In some embodiments, the patterned layer 1016a comprises a patterned die attach film, for example, comprising an adhesive electrically insulating material in electrically insulating region 1012a and an electrically conductive adhesive as electrical conductor 1008a.

FIG. 10B shows examples cells in a shingle arrangement. Cell 1020a as shown in FIG. 10A and cell 1020b. Cell 1020b includes a wafer foil 1006b having a first side 1005b and a second side 1007b opposite the first side. Cell 1020b includes a front metal contact 1004b coupled to the first side 1005b of the wafer foil 1006b and a back metal layer 1002b coupled to the second side 1007b of the wafer foil 1006b. In some examples, the front metal contact 1004b and the back metal layer 1002b act as contacts for the semiconductor device of the wafer foil 1006b (e.g., contacts for a thermophotovoltaic device). The cell 1020b can further include a patterned layer 1016b coupled to the back metal layer 1002b opposite the wafer foil 1006b. The patterned layer 1016b can include an electrically insulating region 1012b and an electrical conductor 1008b that contacts the back metal layer 1002b. In some such examples, the electrical conductor 1008b of the patterned layer 1016b can similarly serve as a contact for the device of the wafer foil 1006b, for example, via the back metal layer 1002b.

In some examples, cell 1020a and 1020b are diced from the same wafer system. In some examples, cell 1020a and 1020b are substantially the same in appearance. In the example of FIG. 10B, the electrical conductor 1008a of the patterned layer 1016a of the first cell 1020a is in electrical communication with the front metal contact 1004b of the second cell 1020b such that the first cell 1020a and the second cell 1020b are electrically connected in series and form a shingle arrangement. As described, in some examples, cells 1020a and 1020b are photovoltaic cells, and in some examples, are thermophotovoltaic cells.

In some embodiments, the patterned layers 1016a and 1016b comprise patterned die attach films, for example, comprising an adhesive electrically insulating material in electrically insulating regions 1012a, 1012b and an electrically conductive adhesive as electrical conductors 1008a, 1008b. In some examples, a patterned die attach film can be used to provide adhesion from a particular cell (e.g., 1020a) to an underlying surface, such as an adjacent cell in a shingle arrangement (e.g., 1020b) and/or a substrate for, for example, an interconnected device comprising a plurality of cells in a shingle arrangement. Additionally or alternatively, a patterned die attach film can provide thermal contact between a cell and an underlying surface, such as adjacent cell and/or substrate. In some examples, electrically conductive and electrically insulating portions of a patterned die attach film can be thermally conductive, for example, to dissipate heat to an underlying device (e.g., a cold-plate) when one or more cells (e.g., interconnected cells) comprise thermophotovoltaic devices. The electrical conductivity of various portions of the patterned die attach film can provide the desired electrical communication, such as selectively providing electrical conductivity to a back metal layer (e.g., 1002a) of one cell for contacting a front metal contact (e.g., 1004b) of another cell while otherwise insulating the back metal layer from making electrical contact with other components.

While shown in the example of FIGS. 10A and 10B as including a single electrical conductor (e.g., 1008a, 1008b), cells can be made to include multiple conductive regions within a patterned layer (e.g., within a patterned die attach film) to provide electrical communication between select portions of a cell (e.g., back metal layer 1002a) and an underlying component. The size, shape, and/or location of such conductive regions can be configured, for example, based on a desired interconnected device structure.

As noted, in some examples, the wafer foil comprises a thermophotovoltaic wafer foil, and in some embodiments, the electrical insulating region of the patterned layer comprises a thermally conductive, electrically insulating material. A thermally conductive layer can help to dissipate heat that might otherwise be generated within the thermophotovoltaic device. In some embodiments, an interconnected device comprising cells having thermally conductive layers can be positioned on a cold-plate, for example, to further dissipate heat from the thermophotovoltaic device.

In some embodiments, the wafer foil comprises one or more semiconductor layers, for example, for use in thermophotovoltaic applications. In some examples, the wafer foil comprises n-type and p-type III-V semiconductor layers, such as GaAs, InGaAs, InP, AlInGaAs, InGaAsP, GaInNAs, InN, or GaSb, or combinations or alloys thereof. In some examples, the wafer foil comprises n-type and p-type group IV semiconductor layers, such as Si, Ge, Sn, SiSn, GeSn, SiGeSn, or combinations or alloys thereof. In some examples, the wafer foil comprises n-type and p-type II-VI semiconductor layers, such as HgCdTe, HgCdSe, HgCdS, HgZnTe, HgZnSc, HgZnS, or combinations or alloys thereof. In some examples, the wafer foil comprises Zn3As2, CuInSc2, FeS2, Cu2SnS3, Ag2S, VO2, or combinations or alloys thereof.

To facilitate an understanding of the subject matter described herein, many aspects are described in terms of sequences of actions. The description herein of any sequence of actions is not intended to imply that the specific order described for performing that sequence must be followed. All methods described herein may be performed in any suitable order unless otherwise indicated herein or otherwise clearly contradicted by context.

The use of the terms “a” and “an” and “the” and similar references in the context of describing the subject matter (particularly in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. Furthermore, the foregoing description is for the purpose of illustration only, and not for the purpose of limitation, as the scope of protection sought is defined by the claims as set forth hereinafter together with any equivalents thereof. The use of any and all examples, or exemplary language (e.g., “such as”) provided herein, is intended merely to better illustrate the subject matter and does not pose a limitation on the scope of the subject matter unless otherwise claimed. The use of the term “based on” and other like phrases indicating a condition for bringing about a result, both in the claims and in the written description, is not intended to foreclose any other conditions that bring about that result. No language in the specification should be construed as indicating any non-claimed element as essential to the practice of the invention as claimed.

While specific examples have been provided above, it is understood that the present invention can be applied with a wide variety of inputs, thresholds, ranges, and other factors, depending on the application. For example, the time frames and ranges provided above are illustrative, but one of ordinary skill in the art would understand that these time frames and ranges may be varied or even be dynamic and variable, depending on the implementation.

As those skilled in the art will understand, a number of variations may be made in the disclosed embodiments, all without departing from the scope of the invention, which is defined solely by the appended claims. It should be noted that although the features and elements are described in particular combinations, each feature or element can be used alone without other features and elements or in various combinations with or without other features and elements. The methods or flow charts provided may be implemented in a computer program, software, or firmware tangibly embodied in a computer-readable storage medium for execution by a general-purpose computer or processor.

Various examples have been described. These and others are within the scope of the following claims.

1. A photovoltaic device comprising:
a photovoltaic cell comprising:
a wafer foil having a first side and a second side opposite the first side;
a front metal contact coupled to the first side of the wafer foil;
a back metal layer coupled to the second side of the wafer foil; and
a patterned layer coupled to the back metal layer opposite the wafer foil, the patterned layer comprising an electrically insulating region and an electrical conductor that contacts the back metal layer.

2. The photovoltaic device of claim 1, wherein the wafer foil comprises a thermophotovoltaic wafer foil.

3. The photovoltaic device of claim 2, wherein the electrically insulating region comprises a thermally conductive, electrically insulating material.

4. The photovoltaic device of claim 1, wherein the electrically insulating region and the electrical conductor each comprise a die attach film such that the patterned layer comprises a patterned die attach film.

5. The photovoltaic device of claim 1, wherein
the photovoltaic cell comprises a first photovoltaic cell; and
the photovoltaic device further comprises a second photovoltaic cell comprising:
a second wafer foil having a first side and a second side opposite the first side;
a second front metal contact coupled to the first side of the second wafer foil;
a second back metal layer coupled to the second side of the second wafer foil;
a second patterned layer coupled to the second back metal layer opposite the second wafer foil, the second patterned layer comprising an electrically insulating region and an electrical conductor that contacts the back metal layer.

6. The photovoltaic device of claim 5, wherein the electrical conductor of the patterned layer of the first photovoltaic cell is in electrical communication with the second front metal contact of the second photovoltaic cell such that the first photovoltaic cell and the second photovoltaic cell are electrically connected in series and form a shingle arrangement.

7. The photovoltaic device of claim 6, wherein the electrically insulating region of the patterned layer of the first photovoltaic cell comprises a die attach film.

8. The photovoltaic device of claim 6, wherein the first photovoltaic cell and the second photovoltaic cell form at least part of an interconnected assembly, and wherein the interconnected assembly is coupled to a cold-plate.

9. The photovoltaic device of claim 1, wherein the electrical conductor comprises a conductive epoxy or a solder paste.

10. The photovoltaic device of claim 1, further comprising dicing tape attached to the wafer foil or the patterned layer, wherein the dicing tape is attached to the patterned layer, and wherein a hole in the dicing tape aligns with the electrical conductor of the patterned layer.

11. A wafer system for processing to create a plurality of thermophotovoltaic cells for arranging in a thermophotovoltaic shingle device comprising:
a wafer foil having a first side and a second side opposite the first side;
a plurality of front metal contacts coupled to the first side of the wafer foil and arranged in a front metal pattern;
a metal layer coupled to the second side of the wafer foil;
a patterned layer coupled to the metal layer opposite the wafer foil, the patterned layer comprising a non-conductive insulator and a plurality of electrical conductors arranged in a back pattern.

12. The wafer system of claim 11, wherein the non-conductive insulator comprises a die attach film.

13. The wafer system of claim 11, wherein the non-conductive insulator fills the space around the plurality of electrical conductors.

14. The wafer system of claim 11, further comprising a releasable tape layer.

15. The wafer system of claim 14, wherein the releasable tape layer is coupled to the patterned layer.

16. The wafer system of claim 15, wherein the releasable tape layer comprises a plurality of holes therein, each of the plurality of holes in the releasable tape layer being aligned with a corresponding one of the plurality of electrical conductors of the patterned layer.

17. The wafer system of claim 14, wherein the releasable tape layer is coupled to the second side of the wafer foil and/or the plurality of front metal contacts.

18. The wafer system of claim 14, wherein the releasable tape layer comprises a dicing tape.

19. A method comprising:
providing a wafer system comprising:
a wafer foil having a first side and a second side opposite the first side,
a plurality of front metal contacts coupled to the first side of the wafer foil and arranged in front metal pattern, and
a back metal layer coupled to the second side of the wafer foil, wherein
the wafer system comprises a front side corresponding to the first side of the wafer foil and a back side corresponding to the second side of the wafer foil;
adding a patterned layer to the back side of the wafer system such that the patterned layer is coupled to the back metal layer, the patterned layer comprising a non-conductive insulator and a plurality of electrical conductors arranged in a back pattern.

20. The method of claim 19, further comprising:
attaching dicing tape to the combined wafer system and patterned layer; and
dicing the combined wafer system and patterned layer at intervals into a plurality of cells such that each of the plurality of cells includes only one of the front metal contacts of the wafer system on a first side of the cell and only one of the plurality of electrical conductors of the patterned layer on a second side of the cell, the second side being opposite the first side.

21. The method of claim 20, further comprising:
releasing at least a first cell of the plurality of cells and a second cell from the plurality of cells from the dicing tape; and
electrically coupling the front metal contact on the first side of the first cell to the electrical conductor on the second side of the second cell such that the first cell and the second cell are electrically coupled in series in a shingle arrangement.

22. The method of claim 21, wherein electrically coupling the front metal contact on the first side of the first cell to the electrical conductor on the second side of the second cell such that the first cell and the second cell are electrically coupled in series in a shingle arrangement is done without a step of adding an additional insulation between the first cell and the second cell.

23. The method of claim 21, wherein the non-conductive insulator comprises a die attach film.

24. The method of claim 20, further comprising:
with the front side of the wafer system facing upward, attaching a release tape to front side of the wafer system; and
flipping the wafer system so that the back side of the wafer system faces upward; and wherein
the adding the patterned layer to the back side of the wafer system is performed after flipping the wafer system.

25. The method of claim 24, further comprising:
after adding the patterned layer to the back side of the wafer system, flipping the combined wafer system and patterned layer so that the front side of the wafer system faces upward; and wherein
attaching dicing tape to the combined wafer system and patterned layer comprises attaching the dicing tape to the patterned layer; and
the dicing the combined wafer system and patterned layer is performed with the front side of the wafer system facing upward.

26. The method of claim 24, further comprising:
after adding the patterned layer to the back side of the wafer system, attaching the dicing tape to the front side of the wafer system; and wherein
the dicing the combined wafer system and patterned layer is performed with the front side of the wafer system facing downward.

27. The method of claim 24, further comprising:
releasing at least a first cell of the plurality of cells and a second cell from the plurality of cells from the dicing tape; and
electrically coupling the front metal contact on the first side of the first cell to the electrical conductor on the second side of the second cell such that the first cell and the second cell are electrically coupled in series in a shingle arrangement.

28. The method of claim 27, wherein electrically coupling the front metal contact on the first side of the first cell comprises:
placing the second cell on a surface with the second side of the second cell facing upward and the first side of the second cell facing downward; and
placing the first cell onto the second cell with the first side of the cell facing downward, toward the second side of the first cell, such that the front metal contact on the first side of the first cell contacts the electrical conductor on the second side of the second cell.

29. The method of claim 28, wherein the first cell and second cell in the shingle arrangement form at least part of an interconnected assembly, and wherein the method further comprises:
after placing the first cell onto the second cell with the first side of the cell facing downward, toward the second side of the first cell, such that the front metal contact on the first side of the first cell contacts the electrical conductor on the second side of the second cell, flipping the interconnected assembly such that the first side of the first cell and the first side of the second cell each face upward.

30. The method of claim 19, wherein adding the patterned layer to the wafer system comprises:
adding the non-conductive insulator to the back metal layer of the wafer system;
forming a plurality of holes in the non-conductive insulator; and
applying a conductive material to each of the plurality of holes in the non-conductive insulator to form the plurality of electrical conductors.

31. The method of claim 19, wherein adding a patterned layer to the back side of the wafer system comprises adding a dicing tape to the back side of the wafer system, the dicing tape being combined with a patterned film.

32. The method of claim 31, further comprising the step of releasing the patterned film from the dicing tape such that the patterned film remains on the back side of the wafer system and forms the patterned layer.

33. The method of claim 19, wherein the non-conductive insulator comprises a thermally conductive, electrically insulating material.

34. The method of claim 19, wherein each of the plurality of electrical conductors comprise an electrically conductive adhesive.
